(19) United States
(12) Patent Application Publication
(10) Pub. No.: US 2007/0188054 A1
(43) Pub. Date: Aug. 16, 2007

(54) Surface acoustic wave packages and methods of forming same

(75) Inventors: Randall J. Hasken, Lanark, IL (US); Larry J. Bohnert, Monroe, WI (US); Steven J. Magee, Lena, IL (US)

Correspondence Address: Bryan Anderson;Honeywell International Inc., 101 Columbia Rd., P.O. Box 2245, Morristown, NJ, 07962, US

(73) Assignee: Honeywell International Inc.

(21) Appl. No.: 11/352,828

(22) Filed: Feb. 13, 2006

(51) Int. Cl. H01L 41/053

(52) U.S. Cl. 310/348

(57) ABSTRACT

A sensor package generally includes a substrate and one or more sensing elements, located on a surface of the substrate. A lid, such as for example a glass cap, is coupled to the substrate such that the lid and substrate define a sealed cavity accommodating the sensing element(s). The lid has at least one conductive via or well electrically coupled to the sensing element(s) inside the cavity and arranged so as to provide an electrical connection to the exterior of the lid for connecting with external circuitry. The substrate can be a piezoelectric substrate and each sensing element can consist of an interdigital transducer such that the substrate and interdigital transducer(s) define a surface acoustic wave sensor. A surface acoustic wave sensor system for sensing torque includes the sensor package and leads wire bonded to the conductive vias for attaching the sensor package to an antenna.

### TECHNICAL FIELD

Embodiments are generally related to sensors and methods of packaging same. Embodiments are also related to acoustic wave sensor packages and, more particularly, surface acoustic wave (SAW) sensor packages and methods. Embodiments are additionally related to sensor systems utilizing SAW sensor packages, such as SAW torque sensor systems, and methods of forming such systems.

### BACKGROUND OF THE INVENTION

Discrete sensors formed from sensor dies or chips can have active regions which are particularly sensitive to surrounding mechanical, chemical and/or electrical influences. In order to ensure that the operating characteristics of such sensors are stable and reliable, the sensor dies or chips are generally packaged in sealed enclosures so as reduce or eliminate these undesired influences.

Acoustic wave sensors are examples of discrete sensors which can be highly sensitive to the operating environment. Acoustic wave sensors are utilized in a number of sensing applications, such as, for example, temperature, pressure, humidity and/or gas sensing devices and systems. An acoustic wave (e.g., SAW/BAW) device acting as a sensor can provide a highly sensitive detection mechanism due to the high sensitivity to surface loading and the low noise, which results from their intrinsic high Q factor.

Examples of acoustic wave sensors include devices such as surface acoustic wave (SAW) sensors, which can be utilized to detect the torque or strain in a member or the presence of substances, such as chemicals and biological materials. Surface acoustic wave torque sensing is an emerging technology for automotive, transportation, rail and other similar segments for use in powertrain and chassis applications. SAW devices act as resonators whose resonant frequency changes when they are strained. Working at radio frequencies, devices can be wirelessly excited with an interrogation pulse and a resonant frequency response measured allowing strain to be calculated. Torque can be sensed by using appropriate packaging and algorithms to deduce value of a sensed property from a returned signal.

SAW devices are typically fabricated using photolithographic techniques with comb-like interdigital transducers placed on a piezoelectric material. SAW devices may have either a delay line or a resonator configuration. SAW sensors are particularly sensitive to mechanical surface conditions. The propagation characteristics of surface acoustic waves for example can be strongly affected by the presence of foreign substances in contact with the sensor surface. Consequently, SAW sensors are generally hermetically packaged.

Common forms of packaging for SAW sensors and other discrete sensors requiring sealed enclosures are costly to manufacture because of the high number of parts and processing steps required to package the sensors.

Having regard to the foregoing, there is therefore a need to provide low cost sealed packages for discrete sensors, particularly, surface acoustic wave sensors, such as torque surface acoustic wave sensors.

The embodiments disclosed herein therefore directly address the shortcomings of present sealed packages for discrete sensors, particularly, surface acoustic wave sensors, providing a low cost sealed package and associated method of manufacturing.

### BRIEF SUMMARY

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

It is, therefore, one aspect, to provide for improved sensor packages.

It is another aspect, to provide for low cost sealed packages for discrete sensors, such as surface acoustic wave (SAW) sensors.

It is another aspect, to provide for low cost methods of packaging sensors, such as SAW sensors.

It is yet a further aspect, to provide for low cost surface acoustic wave sensor packages, such as for example SAW torque sensor packages.

It is also another aspect, to provide for a low cost package sensor system, such as a SAW torque sensor system.

The aforementioned aspects of the invention and other objectives and advantages can now be achieved as described herein. A sensor package is disclosed as is a sensor system and method of manufacturing thereof. According to one aspect, the sensor package generally includes a substrate and one or more sensing elements, located on a surface of the substrate. The sensor package also has a lid, such as for example a glass cap, coupled to the substrate such that the lid and substrate define a sealed cavity accommodating the sensing element(s). The lid has at least one conductive via or well which is electrically coupled to the sensing element(s) inside the cavity and which provides an electrical connection to the exterior of the lid for connecting with external circuitry.

Advantageously, fewer component parts and processes are required to manufacture the sensor package as compared to current sealed packages for discrete sensors. Consequently, a sealed sensor package which is compact and low cost can be manufactured.

Fabrication of the sensor package can be implemented by means of semiconductor and integrated circuit fabrication techniques apparent to those skilled in the art further reducing manufacturing costs. Preferably, the sensor package is mass produced by means of wafer level processing techniques and subsequently singulated, which can be separated from adjacent packages, using known wafer dicing methods.

Preferably, the lid has a first surface and a second surface, opposite the first surface, which is coupled to the substrate surface. The conductive via(s) can extend between the first and second surfaces of the lid and can be spaced from the cavity.

The conductive via(s), which can be formed from solder or other conductive material, can be electrically coupled to the sensing element(s) by means of one or more conductive layers or pads, such as gold or other metal pads, which are interposed between the second surface of the lid and the substrate surface and in contact with the conductive via(s).

Preferably, the one or more conductive vias form one or more solder wells on the exterior of the lid such that one or more wires can be soldered in or on the solder well(s).

Preferably, the substrate consists of a piezoelectric substrate and each sensing element can include an electrode, such as an interdigital transducer, such that the piezoelectric substrate and electrode(s) define a surface acoustic wave sensor.

The lid can provide the electrical and mechanical connections to the outside of the sensor package in addition to providing a sealing zone above the interdigital transducers. Consequently, this enables the surface acoustic wave sensor package to be fabricated using less parts and components and fewer processing steps so that the sensor can be packaged in a low cost manner.

According to another aspect, a surface acoustic wave sensor system comprises a sensor package having a surface acoustic wave sensor. The surface acoustic wave sensor consists of a substrate of piezoelectric material and one or more interdigital transducers located on a surface of the substrate. The sensor package also has lid which is coupled to the substrate such that the lid and substrate define a sealed cavity accommodating the interdigital transducer(s) therein. The lid can have one or more conductive vias which are spaced from the cavity and which are electrically coupled to the interdigital transducer inside the cavity so that the conductive via(s) provide an electrical connection to the exterior of the lid for connecting with external circuitry.

The lid can have a first surface, a second surface, opposite the first surface, and at least one conductive via extending between the first and second surfaces. The one or more conductive vias can be electrically coupled to the sensing element(s) by means of one or more conductive layers or pads interposed between the second surface of the lid and the substrate surface. Each conductive via can have an end located at the second surface of the lid which end is aligned and in contact with each conductive pad.

Preferably, the sensor system can include one or more wires bonded to a region of the conductive vias at the first surface of the lid for electrically attaching the sensor package to an antenna. The conductive via(s) can be solder vias or wells and the wire(s) can be reflow soldered thereto.

Preferably, the surface acoustic wave sensor is a torque or strain sensor. The sensor package can be attached to the surface of a member such that the surface acoustic wave sensor can measure the strain or torque of the member. The sensor package and wire bonding can be encapsulated using epoxy or other suitable sealant on the member surface for electrical and environmental protection.

Preferably, the sensor package is fabricated using semiconductor and/or micro electro mechanical system (MEMS) equipment and fabrication techniques.

According to yet another aspect, a method of forming a sensor package system is disclosed. The method consists of providing a substrate having one or more sensing elements thereon, forming one or more conductive pads on the substrate in electrical contact with a corresponding sensing element, forming a lid having one or more througholes, aligning the lid with the substrate with each throughhole aligned with each conductive pad, and attaching the lid on the substrate such that the substrate and lid define a sealed cavity accommodating the sensing element(s), the conductive pad(s) interposing the lid and substrate and sealing one end of the throughhole(s) so as to define one or more wells.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a cross-sectional view of a sensor package in accordance with a preferred embodiment;

FIG. 2 illustrates a perspective view of the sensor die of FIG. 1 unpackaged;

FIG. 3 illustrates a cross-sectional view depicting the formation of the conductive pads on the substrate of the sensor die shown in FIG. 2;

FIG. 4 illustrates a cross-sectional view depicts formation of the lid of the sensor package of FIG. 1,

FIG. 5 illustrates a cross-sectional view depicting attachment of the lid on the substrate and conductive pads shown in FIG. 3;

FIGS. 6 & 7 illustrate cross-sectional views of a torque sensor system including the sensor package of FIG. 1.

### DETAILED DESCRIPTION

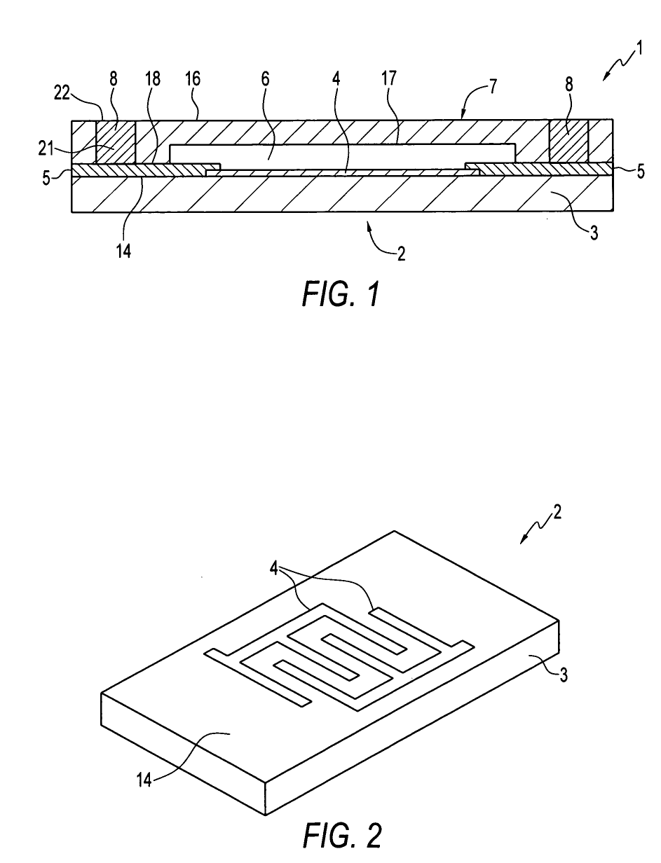

Referring to FIG. 1 of the accompanying drawings, which illustrates a cross-sectional view of a sensor package according to one embodiment, a sensor package 1 generally has a sensor die 2 and a lid 7 coupled to the sensor die such that the lid and die define a sealed cavity 6, which preferably is hermitically sealed, in which sensing elements 4 of the sensor die are accommodated. Lid 7 includes a pair of conductive vias or wells 8 electrically isolated from one another and spaced from the cavity 6.

The conductive vias 8 are electrically coupled to the sensing elements 4, located within the cavity 6, and extend to an exterior surface of the lid 7 allowing signals related to the sensing elements to pass between the sealed cavity and the exterior of the sensor package 1. As will be explained in more detail below, wires or other electrical components for passing signals between the sensing elements 4 and external circuitry can be mechanical and electrically connected to the sensor package by simply conductively bonding the wires to or in the conductive vias exposed on the outside of the lid.

Advantageously, a reduced number of component parts and processes are required to manufacture the sensor package as compared to current sealed sensor packages. Consequently, a sealed sensor package which is compact and low in cost can be produced.

Fabrication of the package can be implemented by means of semiconductor and integrated circuit fabrication techniques apparent to those skilled in the art further reducing manufacturing costs. Preferably, the sensor package is mass produced by means of wafer level processing techniques and subsequently singulated, that is, separated from adjacent packages, using known wafer dicing methods.

As best shown in FIG. 2, which illustrates a perspective view of the sensor die of FIG. 1 unpackaged, sensor die 2 consists of a substrate 3 fabricated from a piezo electric material, such as quartz, and sensing elements 4 arranged on the upper surface 14 of the substrate. In the illustrative embodiment, sensing elements 4 consist of a pair of electrodes in the form of interdigital transducers (IDT) 4 arranged on the upper surface 14 so as to form a surface acoustic wave sensor 2 for sensing torque or strain of a member. However, those skilled in the art would understand that sensing elements other than interdigital transducers and substrates other than piezoelectric substrates can be employed for the purpose of providing alternative sensor dies for sensing physical properties other than torque or strain.

Referring to FIGS. 1 & 2, lid 7 consists of a cap 7 fabricated from glass, such as Pyrex® glass. Note Pyrex® is a registered trademark of Corning Glass Corporation New York 14831. Lid 7 has an upper surface 16, a recess 17 on the underside of the lid and a lower outer surface 18, surrounding recess 17, which is sealed on the upper surface 14 of the substrate 3 to create the sealed cavity 6. The lid 7, however, can have alternative forms and can be made from material other than glass, such as for example plastic or other insulating materials or even semi-conducting materials which are suitable for electrically isolating the conductive vias 8 from one another.

The conductive vias 8 are formed from conductive bonding material, such as for example solder, conductive epoxy or other suitable materials apparent to those skilled in the art. In this particular embodiment, the conductive vias 8 are located in a peripheral region of the lid 7 on either side of cavity 6 and extend between the upper surface 16 and the lower outer surface 18 of the lid. A pair of conductive pads 5 interposes the lid lower outer surface 18 and the substrate upper surface 14 such that the conductive pads 5 are in electrical contact with the lowermost ends 21 of respective conductive vias 8. The conductive pads 5 extend into the cavity 6 along the upper surface 14 of the substrate where they are electrically connected to respective interdigital transducers 4 thereby electrical coupling the conductive vias 8 to the respective interdigital transducers.

The lid 7 therefore provides the electrical and mechanical connections to the outside of the sensor package 1 in addition to providing a sealing zone above the interdigital transducers 4. Consequently, this enables the sensor package 1 to be fabricated using less parts and components and fewer processing steps so that the sensor can be packaged in a low cost manner.

A method of manufacturing a sensor package will now be described with reference particularly to FIGS. 1 & 3 to 5 which depict the general packaging method according to one embodiment.

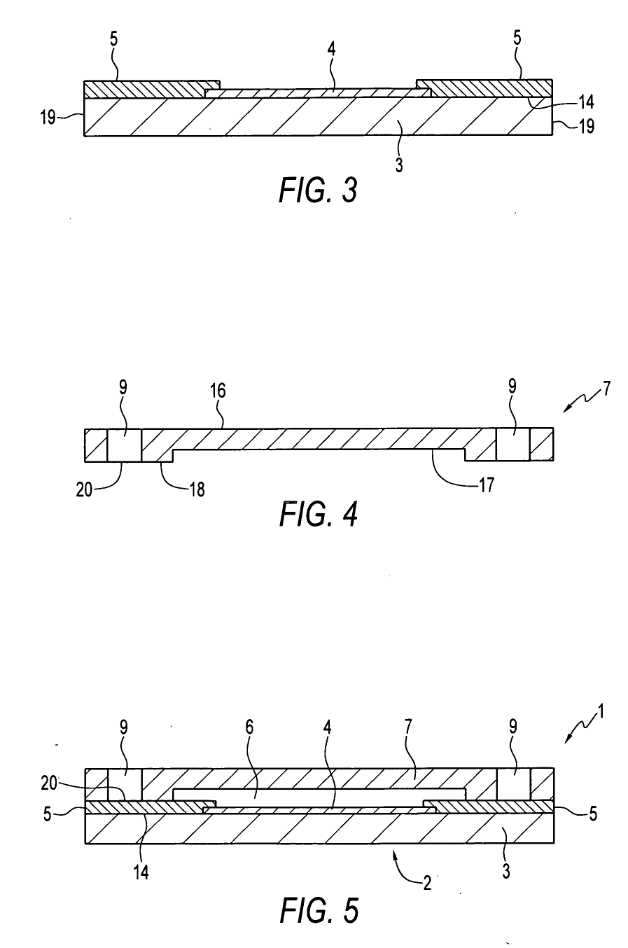

Referring to FIG. 3, which illustrates the formation of conductive pads on the sensor die of FIG. 2, the general method includes forming a pair of conductive pads 5 on the upper surface 14 of the substrate 3 either side of interdigital transducers 4. Formation of the conductive pads 5 can be achieved by means of depositing metal, such as gold, or other conductive materials on the substrate by known deposition techniques, such as for example physical or chemical vapor deposition. The conductive pads 5 are formed on the substrate so as to be in electrical contact with respective interdigital transducers 4 and extend to respective opposite edges 19 of the substrate.

As best shown in FIG. 4, which illustrates a cross-sectional view depicting formation of the lid of the sensor package shown in FIG. 1, a lid 7, which preferably is a glass cap, is provided having an upper surface 16, a central recess 17 on the underside of the lid and a lower outer surface 18, surrounding recess 17. A pair of throughholes 9 are formed in the lid 7, isolated from one another and dimensioned for holding conductive bonding material therein. During manufacture of the lid, for example when the lid is in its green, pliable state, the throughholes 9 are formed by means of laser drilling or etching as is apparent to those skilled in the art. Throughholes 9 are arranged on either side of and spaced from central recess 17 and extend between the upper surface 16 and the lower outer surface 18.

Preparatory to attaching the lid 7 on the upper surface 14 of the substrate 3, the lid is held in alignment with the substrate so that the throughholes 9 are aligned with respective conductive pads 5. The lower outer surface 18, which serves as a sealing surface 18, is then sealed on an outer sealing region of the substrate upper surface 14 and conductive pads 5 so as to create a sealed cavity 6, which preferably, is hermetically sealed, as shown in FIG. 5. The recess 17 is dimensioned such that the active region of the sensor, that is the interdigital transducers 4 and any electrical interconnections between the conductive pads 5 and the interdigital transducers, is accommodated and sealed within the cavity 6. The lid sealing surface 18 is located on the conductive pads 5 so that the conductive pads are sandwiched between the sealing surface 18 and the outer region of the upper surface 14 of the substrate and seal bottom ends 20 of respective throughholes 9 to define wells for holding conductive bonding material.

In order to ensure that the cavity 6 can be adequately sealed, preferably hermetically, the lid sealing surface 18 or the substrate 3 can be profiled in order to accommodate the thickness of the conductive pads 5. Alternatively, the conductive pads 5, together with any electrical interconnections interconnecting pads 5 to the interdigital transducers 4, can be formed embedded in the substrate (not shown) such that the upper surfaces of the pads 5 and any associated interconnections together with the upper surface 14 form a substantially planar surface which is sealable to the corresponding planar lid sealing surface 18.

The lid 7 and substrate 3 can be sealed together by various means. For example, the glass lid can be sealed to the substrate by means of a thermal electric (TE) bonding process in which the lid is heated to a high temperature, placed in contact with the substrate, preferably a semiconductor substrate, and then a voltage is subsequently applied across the sealing interface for a predetermined time period. These parameters are dependant on the types of glass lid and substrate. For example, if the lid is fabricated from Pyrex glass, the lid is heated to about 500° C. and a voltage of 1500 volts is applied across the junction between the lid and substrate for about one minute thereby thermally electrically bonding the lid 7 to the substrate 3. The thermal electric bonding process can be performed utilizing microelectronic fabrication techniques, if desired. Also, if desired, the bonding can be carried out in a vacuum so as to form a vacuum inside the cavity.

Alternatively, the lid can be sealed to the substrate by applying a suitable epoxy or other adhesive to the lid sealing surface 18 and/or corresponding sealing region of the substrate and bonding the lid and substrate in contact with one another. If necessary, a sealing ring can be employed between the lid sealing surface and corresponding sealing region of the substrate.

The throughholes 9 are subsequently filled or coated with conductive bonding material, in this example solder, so as to define conductive wells or vias 8 as shown in FIG. 1. The bottom ends 21 of the conductive vias 8 are in electrical contact with the respective conductive pads 5 and therefore the interdigital transducers. The top ends 22 of the conductive vias 8 located at the lid upper surface 16 serve as mechanical and electrical access points from the exterior of the sensor package.

Preferably, the method is performed at the wafer level using conventional semiconductor and micro electro mechanical system (MEMS) equipment and fabrication techniques. Wafer level assembly is performed using known wafer aligners or pick and place machinery, for example those currently used to fabricate silicon integrated circuits. Such aligners position the wafer on which the substrate 3, sensing elements 4 and conductive pads 5 are fabricated, relative to the wafer on which the lids 7 are fabricated such that the lids are held in alignment with the corresponding substrates. The lid and substrate of each package is then bonded together within a bonding chamber and solder is deposited in the wells forming the conductive vias 8.

Thereafter, the sensor package 1 is singulated using known dicing or sawing techniques so as to separate the sensor packages from adjacent packages or other devices. Insulated wire leads can be wire bonded to the conductive vias by reflowing the solder wells or vias using known solder reflow techniques. For a more reliable mechanical and electrical connection, the lead ends can be inserted into the throughholes during the reflow process and bonded therein.

In the illustrative embodiment, the sensor die 2 is a surface acoustic wave torque sensor having a piezoelectric substrate 3 and interdigital transducers 4 formed on the substrate surface. However, the packaging method can be utilized for packaging other types of sensor dies.

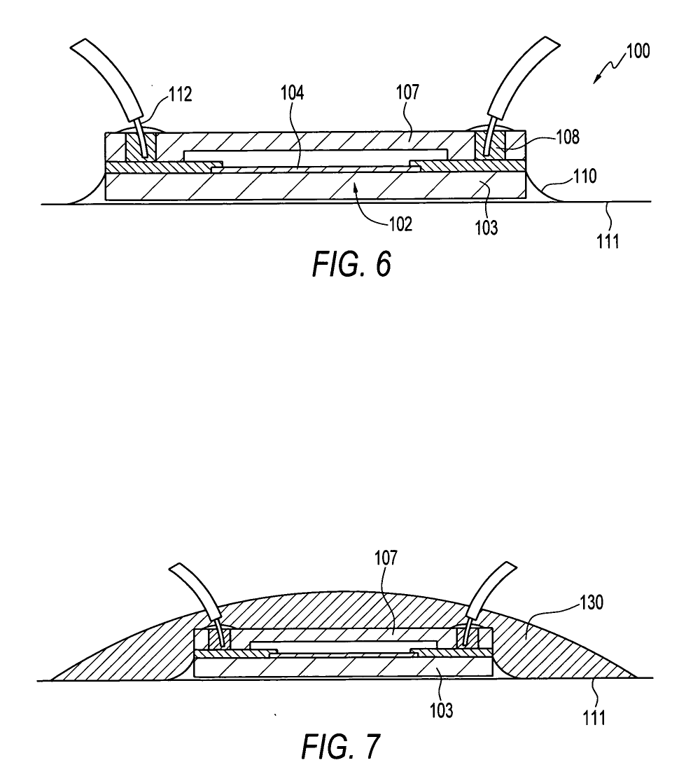

Referring now to FIG. 6, which illustrates a cross-sectional view of a torque sensor package system according to one embodiment, the torque sensor package system 100 consists of a sensor package 101 which is identical to the sensor package 1 of the first embodiment shown in FIG. 1 and which is bonded using a suitable adhesive to the surface 111 of a shaft whose torque is to be measured by the surface acoustic wave sensor 102 of the sensor package. Insulated wire leads 112 for passing signals between the interdigital transducers 104 of the surface acoustic wave sensor 102 and external antennas (not shown) are wire bonded using solder or other conductive bonding material to the conductive vias or wells 108. The conductive vias or wells 108 serve as solder pots in which the ends of the leads 112 are attached. As shown in FIG. 7, which illustrates the same cross-sectional view as FIG. 6 but after encapsulating the sensor package 101, an encapsulant 130 is applied over the entire sensor package 101 and a region of the shaft surface 111 surrounding the package so as to environmentally protect the package 101 and electrical seal the electrical connections between the wire leads 112 and the conductive vias 108. The insulated wires 112 therefore provide electrical access to the exterior of the encapsulated sensor package.

In this particular embodiment, formation of the conductive vias 108 and/or subsequent bonding of the insulated wire leads can be performed after or prior to bonding the sensor package 101 to the member.

The description as set forth is not intended to be exhaustive or to limit the scope of the invention. Many modifications and variations are possible in light of the above teaching without departing from the scope of the following claims. For example, those skilled in the art would understand that the sensor package, as shown in the illustrative embodiments herein, could have any number of conductive vias and corresponding sensing elements. Also those skilled in the art would understand that the sensor package could have other sensing dies, such as for example temperature, speed and position sensing dies. It is contemplated that the use of the present invention can involve components having different characteristics. It is intended that the scope of the present invention be defined by the claims appended hereto, giving full cognizance to equivalents in all respects.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered.

The embodiments of the invention in which an exclusive property or right is claimed are defined as follows. Having thus described the invention what is claimed is:

1. A sensor package apparatus, comprising:
a substrate;
at least one sensing element, located on a surface of said substrate; and
a lid coupled to said substrate such that said lid and said substrate define a sealed cavity accommodating said at least one sensing element, said lid having at least one conductive via or well being electrically coupled to said at least one sensing element in said cavity and being arranged in said lid to provide an electrical connection to an exterior thereof for connecting to external circuitry.

2. The apparatus of claim 1, wherein said lid comprises a first surface and a second surface, opposite said first surface, said second surface being coupled to said substrate surface and wherein said at least one conductive via is spaced from said cavity and extends between said first and second surfaces of said lid.

3. The apparatus of claim 2, wherein said at least one conductive via is electrically coupled to said at least one sensing element by at least one conductive pad interposed between said second surface of said lid and said substrate surface, said at least one conductive via contacting said at least one conductive pad.

4. The apparatus of claim 3, wherein said at least one conductive via forms a solder well on the exterior of said lid such that a wire can be soldered in or on said solder well.

5. The apparatus of claim 1, wherein said substrate comprises a piezoelectric substrate and wherein said at least one sensing element comprises an electrode, said piezoelectric substrate and at least one electrode defining a surface acoustic wave sensor.

6. The apparatus of claim 5, wherein said at least one electrode comprises an interdigital transducer.

7. The apparatus of claim 1, wherein said lid comprises a glass cap.

8. A surface acoustic wave sensor system, comprising:
a sensor package comprising:
a substrate of piezoelectric material;
at least one interdigital transducer, located on a surface of said substrate; and
a lid coupled to said substrate such that said lid and said substrate define a sealed cavity accommodating said at least one interdigital transducer therein, said lid having at least one conductive via spaced from said cavity, said at least one conductive via being electrically coupled to said interdigital transducer in said cavity and being arranged in said lid so as to provide an electrical connection to the exterior thereof for connecting to external circuitry

9. The system of claim 8, wherein said lid has a first surface, a second surface opposite said first surface, and wherein said at least one conductive via extends between said first and second surfaces.

10. The system of claim 8, wherein said at least conductive vias is electrically coupled to at least one sensing element by means of at least one conductive layer or pad interposed between said second surface of said lid and said substrate surface, each conductive via having a end located at said second surface of said lid in contact with each conductive pad.

11. The system of claim 8, further comprising at least one wire bonded to a region of said at least one conductive vias at said first surface of said lid for electrically attaching said sensor package to an antenna.

12. The system of claim 11, wherein said at least one wire is reflow soldered to said at least one conductive via or well.

13. The system of claim 11, wherein said surface acoustic wave sensor is a torque or strain sensor and wherein said sensor package is attached to the surface of a member such that said surface acoustic wave sensor can measure the strain or torque of said member.

14. The system of claim 13, wherein said sensor package and said wire bonding is encapsulated on said member surface for electrical and environmental protection.

15. The system of claim 8, wherein said sensor package is fabricated using semiconductor and/or micro electro mechanical system (MEMS) equipment and fabrication techniques.

16. A method of forming a sensor package system comprising:
providing a substrate having at least one sensing element thereon;
forming at least one conductive pad on said substrate in electrical contact with a corresponding sensing element;
forming a lid having at least one throughole;
aligning said lid with said substrate, said at least one throughhole being aligned with a corresponding conductive pad; and
attaching said lid on said substrate such that substrate and said lid define a sealed cavity accommodating said at least one sensing element, each conductive pad interposing said lid and said substrate and sealing an end of each throughhole so as to define one or more wells.

17. The method of claim 16, further comprising filling or coating said at least one throughhole with conductive material so as to define one or more conductive wells, said at least one conductive well being electrically coupled to said at least one sensing element and providing an electrical connection on the exterior of said lid for connecting to external circuitry.

18. The method of claim 17, wherein said substrate comprises a piezoelectric material and wherein said at least one sensing element comprises an interdigital transducer, said piezoelectric substrate and said interdigital transducer defining a surface acoustic wave sensor.

19. The method of claim 18, further comprising bonding or connecting at least one wire lead to or in said at least one well.

20. The method of claim 19, wherein attaching said lid on said substrate comprises thermal electrically (TE) bonding said lid to said substrate.
